(19) United States
(12) Patent Application Publication
(10) Pub. No.: US 2005/0110083 A1
(43) Pub. Date: May 26, 2005

(54) Metal-oxide-semiconductor device having improved gate arrangement

(76) Inventors: Peter Ledel Gammel, Millburn, NJ (US); Muhammed Ayman Shibib, Wyomissing, PA (US); Zhijian Xie, Belle Mead, NJ (US); Shuming Xu, Schnecksville, PA (US)

Correspondence Address: Ryan, Mason & Lewis, LLP, 90 Forest Avenue, Locust Valley, NY, 11560, US

(21) Appl. No.: 10/719,197

(22) Filed: Nov. 21, 2003

(51) Int. Cl. H01L 29/76

(52) U.S. Cl. 257/343

(57) ABSTRACT

An MOS device comprises a semiconductor layer of a first conductivity type and first and second source/drain regions of a second conductivity type formed in the semiconductor layer proximate an upper surface of the semiconductor layer. The first and second source/drain regions are spaced laterally apart relative to one another and are formed in an active region of the semiconductor layer. The MOS device further comprises a gate formed above the semiconductor layer proximate the upper surface of the semiconductor layer and at least partially between the first and second source/drain regions. The gate is configured such that a dimension of the gate, defined substantially parallel to at least one of the first and second source/drain regions, is confined to be substantially within the active region of the device. An isolation structure is formed in the semiconductor layer, the isolation structure being configured to substantially isolate the first source/drain region from the second source/drain region.

### FIELD OF THE INVENTION

The present invention relates generally to semiconductor devices, and more particularly relates to techniques for improving high-frequency performance in a metal-oxide-semiconductor (MOS) device.

### BACKGROUND OF THE INVENTION

Power MOS devices, including laterally diffused metal-oxide-semiconductor (LDMOS) devices, are employed in a variety of applications, such as, for example, power amplifiers in wireless communications systems. In applications where high-frequency operation is desired, such as in a radio frequency (RF) range (e.g., above 1 gigahertz (GHz)), the capacitance and/or resistance associated with a gate of the MOS device can become a critical factor significantly affecting the high-frequency performance of the device. As such, various methodologies have been proposed for reducing the capacitance and/or resistance of the gate.

For example, previous attempts have been utilized which seek to reduce the gate resistance, including saliciding the gate polysilicon to reduce the resistance of the gate and minimizing the length of polysilicon-gate interconnect in the device. Particularly in a power MOS device, the device is often formed as a plurality of finger structures, one of such finger structures 100 being depicted in FIG. 1. Typically, attempts at reducing the gate resistance of the MOS device have involved connecting both ends 102 of the polysilicon gate 104 of each finger structure 100 to one another via a metal interconnect 106.

A disadvantage, however, with these known techniques is that while a reduction in gate resistance may be achieved, a gate capacitance associated with the device is typically undesirably increased, due at least in part to an increase in extrinsic (e.g., parasitic) capacitance at the ends 102 of each finger structure 100 where the metal interconnect 106 is connected to the polysilicon gate 104 in a thick-oxide region of the device. This extrinsic capacitance may be as high as twenty percent of the total input (e.g., gate-source) capacitance, thereby effectively eliminating any benefit obtained from the reduction in gate resistance. Furthermore, the gate resistance has an extrinsic portion associated therewith due, at least in part, to extensions 108 of the polysilicon gate beyond an active region 110 of the device for providing a connection area for the metal interconnect 106.

There exists a need, therefore, for an MOS device capable of improved high-frequency performance. Furthermore, it would be desirable if such an MOS device was fully compatible with a CMOS process technology so that the cost of manufacturing the device is not significantly increased.

### SUMMARY OF THE INVENTION

In accordance with one aspect of the invention, an MOS device comprises a semiconductor layer of a first conductivity type and first and second source/drain regions of a second conductivity type formed in the semiconductor layer proximate an upper surface of the semiconductor layer. The first and second source/drain regions are spaced laterally apart relative to one another and are formed in an active region of the semiconductor layer. The MOS device further comprises a gate formed above the semiconductor layer proximate the upper surface of the semiconductor layer and at least partially between the first and second source/drain regions. The gate is configured such that a dimension of the gate, defined substantially parallel to at least one of the first and second source/drain regions, is confined to be substantially within the active region of the device. An isolation structure is formed in the semiconductor layer, the isolation structure being configured to substantially isolate one or more portions of the first source/drain region from corresponding portions of the second source/drain region.

The present invention provides techniques for improving a high-frequency performance of an MOS device by substantially reducing an extrinsic capacitance associated with a gate of the device. This may be accomplished, in an illustrative embodiment of the invention, by confining the gate to be within an active region of the device. Moreover, the techniques of the present invention can be used to fabricate an integrated circuit (IC) device, for example, an LDMOS device, using conventional CMOS compatible process technology. Consequently, the cost of manufacturing the IC device is not significantly increased.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a top plan view of at least a portion of a conventional MOS device formed in a semiconductor wafer.

FIG. 2A is a top plan view illustrating at least a portion of an exemplary MOS device, formed in accordance with an illustrative embodiment of the present invention.

FIG. 2B is a top plan view illustrating at least a portion of a traditional MOS device.

FIG. 2C is a cross-sectional view depicting at least a portion of the MOS device illustrated in FIG. 2B.

FIG. 2D is a cross-sectional view depicting at least a portion of an exemplary MOS device shown in FIG. 2A.

FIG. 3A is a top plan view illustrating at least a portion of the MOS device shown in FIG. 2A with the addition of a metal interconnection layer, formed in accordance with an illustrative embodiment of the invention.

FIG. 3B is a top plan view illustrating at least a portion of the traditional MOS device shown in FIG. 2B with the addition of a metal interconnection layer.

FIG. 4 is a top plan view depicting at least a portion of an exemplary MOS device, formed in accordance with another embodiment of the invention.

### DETAILED DESCRIPTION OF THE INVENTION

The present invention will be described herein in the context of an illustrative CMOS integrated circuit fabrication technology suitable for forming discrete RF LDMOS transistors, as well as other devices. It should be appreciated, however, that the present invention is not limited to the fabrication of this or any particular device. Rather, the invention is more generally applicable to techniques for forming an MOS device comprising a novel gate arrangement which advantageously enables the MOS device to provide improved high-frequency performance, while concurrently reducing the size of the device. Moreover, the gate structure is fully compatible with a CMOS process technology, and thus the cost of manufacturing the device is not significantly increased. Although implementations of the present invention are described herein with specific reference to an LDMOS device, it is to be appreciated that the techniques of the present invention are similarly applicable to other devices, such as, but not limited to, an MOS field-effect transistor (MOSFET) device, a vertical diffused MOS (DMOS) device, an extended drain MOS device, etc., with or without modifications thereto, as will be understood by those skilled in the art.

It is to be understood that the various layers and/or regions shown in the accompanying figures may not be drawn to scale, and that one or more semiconductor layers and/or regions of a type commonly used in such integrated circuit structures may not be explicitly shown in a given figure for ease of explanation. This does not imply that the semiconductor layer(s) and/or region(s) not explicitly shown are omitted in the actual integrated circuit structure.

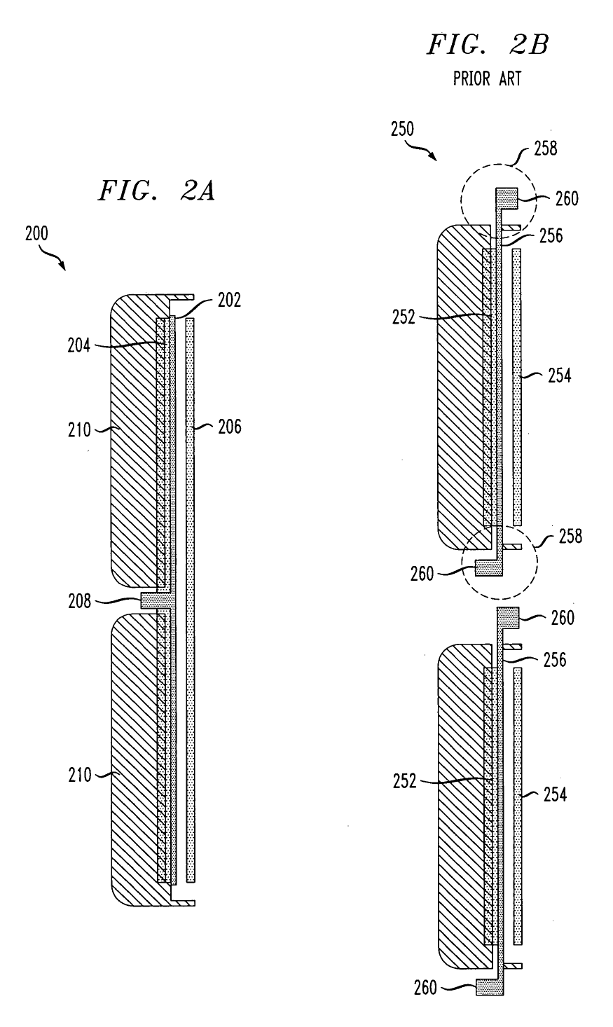

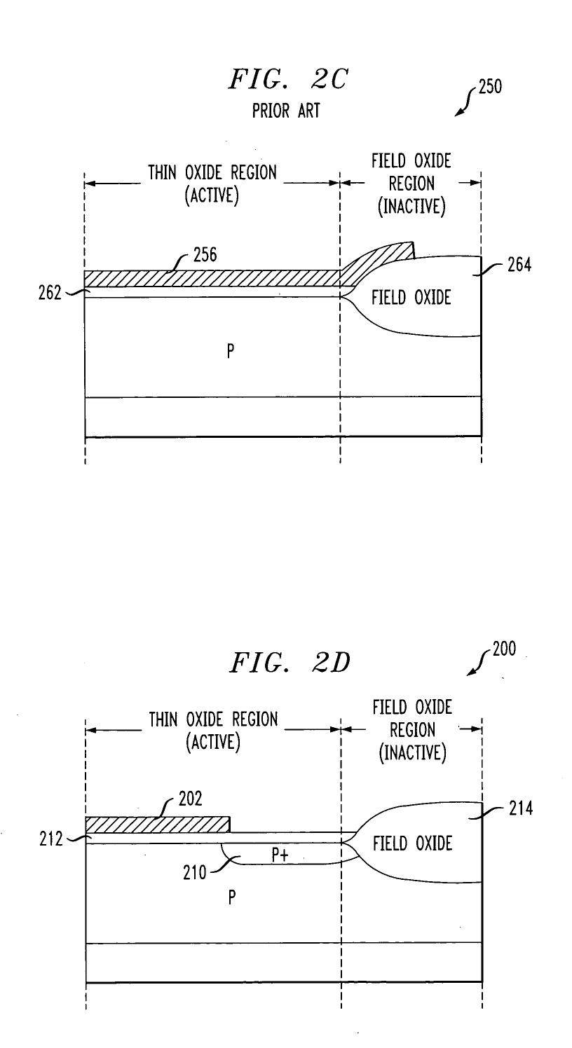

FIG. 2A is a top plan view illustrating at least a portion of a semiconductor wafer in which the techniques of the present invention are implemented. The semiconductor wafer comprises an exemplary MOS device 200 including a source region 204 and a drain region 206 formed in a semiconductor layer of the wafer proximate an upper surface of the semiconductor layer, the source and drain regions being spaced apart laterally relative to one another. In a preferred embodiment of the invention, the source and drain regions are of n-type conductivity. It is to be appreciated that, in the case of a simple MOS device, because the MOS device is symmetrical in nature, and thus bidirectional, the assignment of source and drain designations in the MOS device is essentially arbitrary. Therefore, the source and drain regions may be referred to generally as first and second source/drain regions, respectively, where “source/drain” in this context denotes a source region or a drain region. In an LDMOS device, which is generally not bidirectional, such source and drain designations may not be arbitrarily assigned.

The term “semiconductor layer” as may be used herein refers to any semiconductor material upon which and/or in which other materials may be formed. The semiconductor layer may comprise a single layer, such as, for example, a substrate (not shown), or it may comprise multiple layers, such as, for example, the substrate and an epitaxial layer (not shown). In a preferred embodiment of the invention, the substrate is of p-type conductivity. The semiconductor wafer comprises the substrate, with or without the epitaxial layer, and preferably includes one or more other semiconductor layers formed on the substrate. The term “wafer” is often used interchangeably with the term “silicon body,” since silicon is typically employed as the semiconductor material comprising the wafer. It should be appreciated that although the present invention is illustrated herein using a portion of a semiconductor wafer, the term “wafer” may include a multiple-die wafer, a single-die wafer, or any other arrangement of semiconductor material on or in which a circuit element may be formed.

The exemplary MOS device 200 further includes a gate 202 formed above the source and drain regions and proximate the upper surface of the semiconductor layer. The gate is at least partially formed between the source and drain regions. A width of the exemplary MOS device, which can be defined along a dimension substantially parallel to the source and/or drain regions, is depicted as being substantially greater than a length of the device, which may be defined along a dimension substantially orthogonal to the width, so that the MOS device resembles a finger structure. While depicted as comprising a finger structure, the MOS device 200 is not limited to the precise arrangement shown, and it is to be appreciated that alternative configurations are contemplated by the invention. Moreover, although only one finger structure is shown in FIG. 2A, a power MOS device may comprise a plurality of such finger structures electrically connected in parallel with one another in order to increase the current handling capability of the device.

Gate resistance can significantly attenuate an input signal presented to the gate, particularly at high frequencies (e.g., above about 1 GHz), and therefore it is beneficial to minimize the resistance of the gate 202. The gate typically comprises doped polycrystalline silicon, often referred to simply as polysilicon, which generally has a resistivity in a range of about 30 to about 100 ohms per square. Alternative materials (e.g., metal, etc.) may be similarly used for forming the gate 202, as will be understood by those skilled in the art. While a metal gate may be employed, which typically exhibits a substantially lower resistivity (e.g., about 0.03 ohms per square) in comparison to doped polysilicon, it is generally difficult to define a uniform metal line as is generally necessary for forming precise gate dimensions.

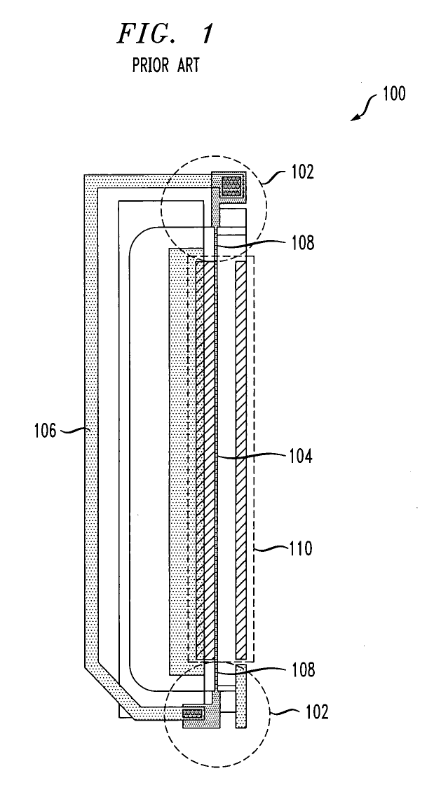

In order to reduce the resistivity of the gate 202, a salicide layer may be formed on at least a portion of the gate using, for example, a conventional saliciding process. The salicide process typically uses tungsten, titanium, cobalt, or other transition metals to form the salicide layer. In this manner, a gate resistivity of less than about one ohm per square can be achieved. In order to further reduce the gate resistance, the metal contacts at the ends of the fingers of the standard MOS device (see FIG. 1) are preferably eliminated and replaced by a single reduced-size contact at a connection area 208 of the gate 202. The connection area 208 is preferably provided proximate a middle of the gate 202.

An important aspect of the present invention is that the unique arrangement of the gate 202 in the exemplary MOS device 200 advantageously provides a substantial reduction in gate capacitance compared to traditional MOS devices. This may be accomplished, in the illustrative embodiment, by reducing an extrinsic capacitance of the gate 202. The term “extrinsic gate capacitance” as used herein is intended to refer to a capacitance between the gate 202 and an area of the semiconductor wafer in which no active junctions are formed. The term “active region” as used herein is intended to refer to an area of the semiconductor wafer wherein active junctions may be formed. Typically, active junctions (e.g., source and drain regions 204,206) are formed in a thin insulating region of the device. The thin insulating region typically comprises a relatively thin layer of silicon dioxide (e.g., about 3000 angstroms for a standard), and may therefore be referred to as a thin oxide region. Other suitable insulating materials (e.g., nitride) may also be employed. A thick insulating region, which may also be referred to as a field oxide (FOX) region, assuming oxide is employed as the insulating material, is typically about three to six times the thickness of the thin insulating region and generally comprises substantially all other areas of the semiconductor wafer outside the defined active region. The thick insulating region may thus be referred to herein as an “inactive region” of the wafer.

FIG. 2B illustrates a traditional MOS device 250 which comprises two identical finger structures, each finger structure including a source region 252, a drain region 254 and a gate 256. The two finger structures, together, substantially equal the source/drain area of the exemplary MOS device 200 shown in FIG. 2A. However, unlike the exemplary MOS device 200, the gate 256 of the traditional MOS device 250 extends substantially beyond the active area of the semiconductor wafer and into an inactive region 258 at each end of the device fingers. The gate 256 in the inactive region 258 of the wafer typically includes a contact area 260 to allow the ends of the gate to be electrically connected together by metal interconnect wiring (not shown) in order to reduce the resistance of the gate 256. It is estimated that the extrinsic gate capacitance resulting from the extension of the gate over the thick oxide area of the wafer is as high as about 20 percent of the overall gate capacitance associated with the device 250. Furthermore, the resistance associated with the gate 256 will increase as a result of the extension of the gate beyond the active region of the wafer. This additional gate resistance, which is estimated to be as high as about 5 percent of the overall gate resistance, may be referred to herein as “extrinsic gate resistance.”

With reference again to FIG. 2A, since the gate 202 is substantially confined within the active region of the wafer, an inversion layer may potentially form between the source and drain regions 204, 206 proximate the ends of the device, thus resulting in leakage when the device is turned off (e.g., zero applied gate-to-source potential). This is generally not a problem in a traditional MOS device because the gate typically extends far enough beyond the source and drain regions to prevent inversion at the ends of the device. Therefore, to substantially eliminate the potential for an inversion layer forming at the ends of the source and drain regions of the exemplary MOS device 200, the device preferably includes an isolation structure formed between the source and drain regions 204, 206, at least proximate the ends of the source and drain regions. The isolation structure preferably comprises a guard ring 210 having a conductivity opposite the conductivity of the source and drain regions 204, 206, although alternative isolation structures suitable for use with the present invention are similarly contemplated.

The guard ring 210 may be formed by doping select portions of the wafer with an impurity (e.g., arsenic, boron, phosphorus, etc.) of a known concentration level, such as, for example, by using an implant or diffusion process, to selectively change the conductivity of the material as desired, as will be understood by those skilled in the art. In a preferred embodiment of the invention, the guard ring is formed having a p-type conductivity, and may therefore be referred to as a p+guard ring. The impurity concentration of the guard ring 210 is preferably substantially matched to the impurity concentration of a semiconductor substrate on which the MOS device may be formed (e.g., about 10¹⁸ to about 10¹⁹ atoms per cubic centimeter).

As apparent from the figure, the p+ guard ring 210 is formed at least substantially surrounding the ends of the source region 204 so as to substantially electrically isolate the source and drain regions 204, 206 from one another. It is to be understood that the present invention is not limited to the precise arrangement of the guard ring 210. Furthermore, as previously stated, the invention contemplates that alternative methodologies may be employed for isolating the source and drain regions, such as, but not limited to, forming one or more isolation trenches (not shown) in the semiconductor wafer at least proximate the ends of the source region 204 and/or drain region 206 of the MOS device 200.

FIGS. 2C and 2D are cross-sectional views depicting at least a portion of the MOS devices shown in FIGS. 2B and 2A, respectively. As shown in FIG. 2C, the gate 256 of the traditional MOS device 250 extends beyond the active region of the device and onto a field oxide region 264 (inactive region) of the device. A thin oxide layer 262 is typically formed under the gate 256 in the active region. With reference to FIG. 2D, in the active region of the exemplary MOS device 200, a thin oxide layer 212 is formed under the gate 202. The inactive region of the device includes a field oxide region 214, as previously explained. In contrast to the traditional MOS structure, however, the gate 202 is confined substantially within the active region of the device. Moreover, a guard ring 210 is formed proximate the upper surface of the wafer and at least partially between the field oxide 214 and an end of the gate 202. The guard ring 210 is preferably formed at least partially beneath the gate 202 at a first end of the guard ring and may extend laterally to the field oxide 214 at a second end of the guard ring, thereby preventing an inversion layer from forming between the source and drain regions, at least proximate the ends of the source and drain regions. As previously stated, alternative means for providing isolation between the source and drain regions of the device are contemplated by the present invention.

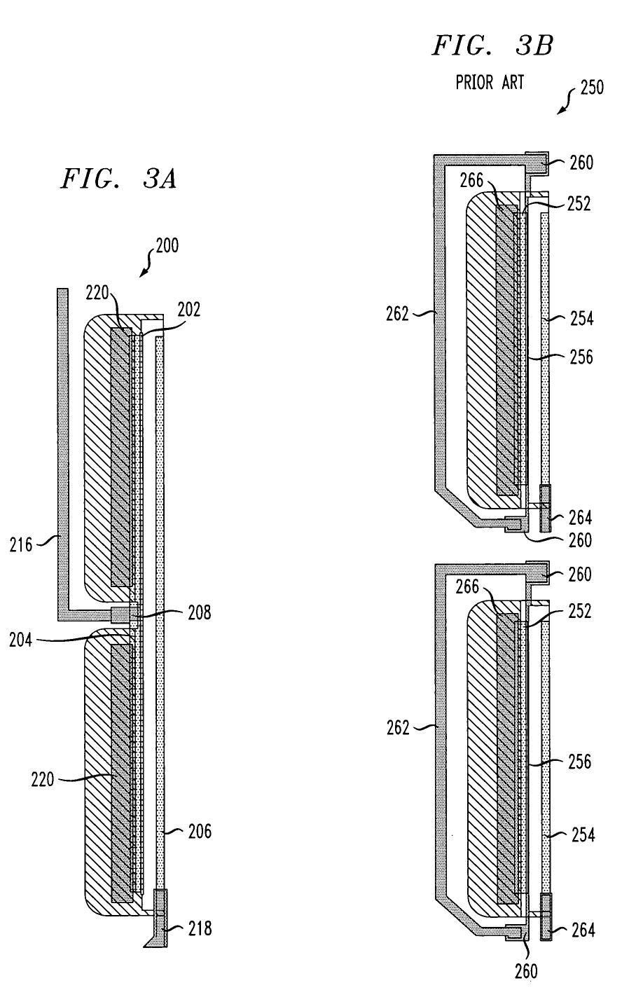

FIGS. 3A and 3B are top plan views illustrating the MOS devices shown in FIGS. 2A and 2B, respectively, with the addition of an interconnection conductive layer. As shown in FIG. 3A, the exemplary MOS device 200 includes a conductive trace 216 for providing electrical connection to the gate 202 at the connection area 208 of the gate. As previously described, connection to the gate 202 is preferably made at a middle of the gate via a single reduced contact rather than the conventional approach of connecting the ends of the gate together via a metal trace, as will discussed herein in conjunction with FIG. 3B. In this manner, extrinsic gate resistance may be substantially reduced, thereby providing further beneficial enhancements in the high-frequency performance of the MOS device 200. Connections 218 and 220 are also provided for electrically contacting the drain and source regions 206 and 204, respectively. In a preferred embodiment of the invention, each of the connections 216, 218,220 to the corresponding gate, drain and source regions comprises a metal (e.g., gold, aluminum, etc.), although alternative methodologies for contacting one or more of the gate, drain and source of the device is contemplated (e.g., doped polysilicon).

As shown in FIG. 3B, the traditional MOS device 250 typically includes a metal interconnection 262 connecting the ends of the gate 256, at the contact areas 260, for each of the finger structures. Metal contacts 264 and 266 are also included for providing electrical connection to the drain region 254 and source region 252 of each finger structure of the device 250.

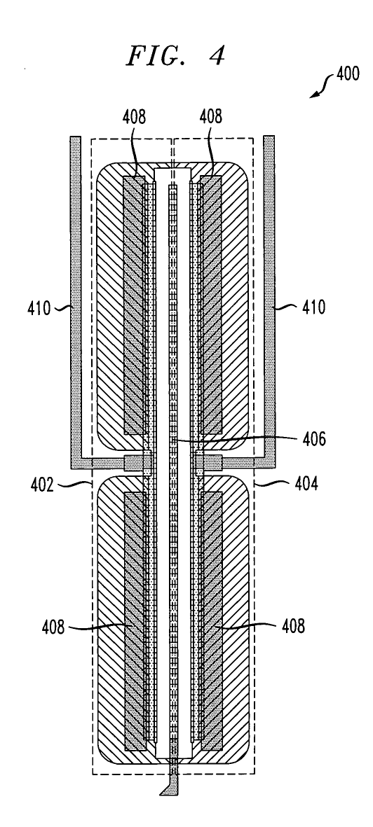

FIG. 4 is a top plan view depicting at least a portion of a semiconductor comprising an exemplary MOS device 400, formed in accordance with another embodiment of the invention. The exemplary MOS device 400 comprises two finger structures. The two finger structures 402 and 404, each of which maybe a mirror image of one another and may share a common drain region 406. The finger structures 402, 404 are preferably formed in a manner similar to the formation of the exemplary device 200 depicted in FIGS. 2A and 3A. Source contacts 408 for each of the finger structures 402, 404 are preferably electrically connected together as are the gate connections 410 so that the two fingers are essentially connected in parallel with one another. In this manner, an MOS device is formed having a higher current handling capability, as previously stated. Numerous other alternative configurations for forming the exemplary MOS device 400 are also contemplated by the invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

1. A metal-oxide-semiconductor device, comprising:
a semiconductor layer of a first conductivity type;
first and second source/drain regions of a second conductivity type formed in the semiconductor layer proximate an upper surface of the semiconductor layer and spaced laterally apart relative to one another, the first and second source/drain regions being formed in an active region of the device;
a gate formed above the semiconductor layer proximate the upper surface of the semiconductor layer and at least partially between the first and second source/drain regions, the gate being configured such that a dimension of the gate, defined substantially parallel to at least one of the first and second source/drain regions, is confined to be substantially within the active region of the device; and
an isolation structure formed in the semiconductor layer, the isolation structure being configured to substantially isolate one or more portions of the first source/drain region from corresponding portions of the second source/drain region.

2. The device of claim 1, wherein the isolation structure is configured to substantially prevent an inversion layer from being formed between the first and second source/drain regions when the device is turned off.

3. The device of claim 1, wherein the isolation structure comprises a guard ring formed in the semiconductor layer proximate the upper surface of the semiconductor layer between at least the one or more portions of the first and second source/drain regions, the guard ring being of the first conductivity type.

4. The device of claim 3, wherein an impurity concentration of the guard ring is substantially matched to an impurity concentration of the semiconductor layer.

5. The device of claim 4, wherein the impurity concentration of the guard ring is in a range from about 10¹⁸ to about 10¹⁹ atoms per cubic centimeter.

6. The device of claim 1, wherein the isolation structure comprises at least one trench formed between at least the one or more portions of the first and second source/drain regions.

7. The device of claim 1, wherein at least one of the one or more portions of the first and second source/drain regions comprises an end of the at least one of the first and second source/drain regions along a dimension substantially orthogonal to the gate.

8. The device of claim 1, wherein the gate comprises a polysilicon layer and a salicide layer formed on at least a portion of the polysilicon layer.

9. The device of claim 1, wherein the gate comprises a connection area for providing electrical connection to the gate, the connection area being proximate a middle portion of the gate along the dimension of the gate defined substantially parallel to at least one of the first and second source/drain regions.

10. The device of claim 1, wherein the first source/drain region comprises a source of the device and the second source/drain region comprises a drain of the device.

11. The device of claim 1, wherein the device comprises a diffused MOS (DMOS) device.

12. The device of claim 1, wherein the device comprises a laterally diffused MOS (LDMOS) device.

13. The device of claim 1, wherein the active region of the device is substantially defined within a thin insulating region of the device.

14. A method of forming a metal-oxide-semiconductor device, the method comprising the steps of:
forming first and second source/drain regions of a second conductivity type in a semiconductor layer of a first conductivity, the first and second source/drain regions being formed proximate an upper surface of the semiconductor layer and spaced laterally apart relative to one another, the first and second source/drain regions being formed in an active region of the device;
forming a gate above the semiconductor layer proximate the upper surface of the semiconductor layer and at least partially between the first and second source/drain regions, the gate being configured such that a dimension of the gate, defined substantially parallel to at least one of the first and second source/drain regions, is confined to be substantially within the active region of the device; and
forming an isolation structure in the semiconductor layer, the isolation structure being configured to substantially isolate one or more portions of the first source/drain region from corresponding portions of the second source/drain region.

15. The method of claim 14, wherein the step of forming the isolation structure comprises forming a guard ring in the semiconductor layer proximate the upper surface of the semiconductor layer between at least the one or more portions of the first and second source/drain regions, the guard ring being of the first conductivity type.

16. The method of claim 15, wherein the step of forming the guard ring comprises matching an impurity concentration of the guard ring to an impurity concentration of the semiconductor layer.

17. The method of claim 14, wherein the step of forming the isolation structure comprises configuring the isolation structure to substantially prevent an inversion layer from being formed between the first and second source/drain regions when the device is turned off.

18. The method of claim 14, wherein the step of forming the isolation structure comprises forming at least one trench in the semiconductor layer between at least the one or more portions of the first and second source/drain regions.

19. The method of claim 14, further comprising the step of forming a salicide layer on at least a portion of the gate, the salicide layer reducing a resistance of the gate.

20. The method of claim 14, wherein the step of forming the gate comprises forming a connection area for providing electrical connection to the gate, the connection area being proximate a middle portion of the gate along the dimension of the gate defined substantially parallel to at least one of the first and second source/drain regions.

21. An integrated circuit including at least one metal-oxide-semiconductor (MOS) device, the at least one MOS device comprising:
a semiconductor layer of a first conductivity type;
first and second source/drain regions of a second conductivity type formed in the semiconductor layer proximate an upper surface of the semiconductor layer and spaced laterally apart relative to one another, the first and second source/drain regions being formed in an active region of the device;
a gate formed above the semiconductor layer proximate the upper surface of the semiconductor layer and at least partially between the first and second source/drain regions, the gate being configured such that a dimension of the gate, defined substantially parallel to at least one of the first and second source/drain regions, is confined to be substantially within the active region of the device; and
an isolation structure formed in the semiconductor layer, the isolation structure being configured to substantially isolate one or more portions of the first source/drain region from corresponding portions of the second source/drain region.

22. The integrated circuit of claim 21, wherein the isolation structure is configured to substantially prevent an inversion layer from being formed between the first and second source/drain regions when the at least one MOS device is turned off.

23. The integrated circuit of claim 21, wherein the isolation structure comprises a guard ring formed in the semiconductor layer proximate the upper surface of the semiconductor layer between at least the one or more portions of the first and second source/drain regions, the guard ring being of the first conductivity type.
